(19) United States
(12) Patent Application Publication
(10) Pub. No.: US 2011/0121817 A1
(43) Pub. Date: May 26, 2011

(54) METHOD FOR INCREASING THE AVAILABILITY OF DISPLACEMENT/POSITION MEASURING SYSTEMS ON THE BASIS OF POTENTIOMETERS WITH A SLIDER TAP (III)

(75) Inventors: Stefan Tabelander, Herford (DE); Thomas Kleegrewe, Minden (DE); Andreas Wahlmann, Meerbeck (DE)

(73) Assignee: ABB Technology AG, Zurich (CH)

(21) Appl. No.: 12/942,376

(22) Filed: Nov. 9, 2010

(30) Foreign Application Priority Data
Nov. 10, 2009 (DE) 10 2009 052 631.5

(51) Int. Cl. G01R 15/08

(52) U.S. Cl. 324/115

(57) ABSTRACT

A method for increasing the availability of displacement/position measuring systems using a potentiometer with a slider tap in a closed control loop. The controller of the potentiometer is formed by a microcontroller which is supplied with the position of the slider via an analog/digital converter. The operating range is shifted within the sensor range in a direction of one of two limits of the operating range at least by a distance between the other of two limits of the operating range and a defective slider position by temporarily interrupting an operative connection between the displacement pick-off on the actuator and the potentiometer shaft.

### RELATED APPLICATION

This application claims priority under 35 U.S.C. §119 to German Patent Application No. 10 2009 052 631.5 filed in Germany on Nov. 10, 2009, the entire content of which is hereby incorporated by reference in its entirety.

### FIELD

The present disclosure relates to potentiometers and to methods, directed to, for example, increasing an availability of displacement/position measuring systems on the basis of potentiometers with a slider tap.

### BACKGROUND

Position measuring systems can be used in electropneumatic position controllers and electrical variable-speed drives to return an actual value and are thus part of a closed control loop. The sudden failure of the position measuring system can thus result in an immediate failure of the device functionality. The availability of the position measuring system is thus restricted.

The structure and method of operation of a closed control loop are known and are described, for example, at <<http://de.wikipedia.org/wiki/Regelkreis>>, portions of which are shown in FIG. 1. For example, in control engineering, five parts illustrated in the control loop are distinguished in a control loop. These five parts include:
1. F_{R}=Control element/controller
2. F_{St}=Actuating element
3. F_{S}=Control path
4. F_{Z}=Interference variable transmission element
5. F_{M}=Measuring element
   And as a result of the above five parts the following variables are generated in the control loop:
w=Reference variable
e=Control error/control difference
yᵣ=Auxiliary manipulated variable/controller output variable
y=Manipulated value/manipulated variable
z=Interference variable
x=Output/controlled variable
r=Feedback variable

The product brochure “Der kompakte, intelligente Stellungsregler” [The compact, intelligent position controller] (ABB Automation Products GmbH, print number: 50/18-19 DE RevA; June 2005 edition) discloses an electronic position controller for a pneumatic actuator. This type of position controller is shown in FIG. 1.

As shown in FIG. 1, the reference variable w can be preset to a desired value channel via an analog 4.20 mA input or a field bus such as HART, Profibus PA, Foundation field bus, or the like.

In this arrangement, the control path F_{S} forms the pneumatic actuator/variable-speed drive to be positioned. The control element F_{R}, the actuating element F_{St} and the measuring element F_{M} are disposed in a housing. The control element F_{R} can be implemented as a microcontroller-supported system. The measuring element F_{M} can be implemented in the form of a otentiometer with a slider tap that measures the set position x of the drive to be controlled. The actuating element F_{St} can be implemented in the form of an IP module in an electropneumatic position controller.

In this instance, the potentiometer is supplied with a constant and known reference voltage, and the position is then detected in an analog-to-digital converter using the displacement-proportional voltage tap. In terms of circuitry, this arrangement includes a voltage divider with a position-dependent voltage tap. The feedback variable “r” is present in digital form in the analog/digital converter. The voltage tap is effected with the highest possible impedance of the measuring circuit in order to minimize measurement errors.

The microcontroller-supported system of FIG. 1, thus forms a controller output variable yᵣ based on a control difference “e” with the aid of a suitable control algorithm in the controller F_{R}, which output variable can be used to drive the IP module via a suitable electronic circuit.

In some special applications, the position sensor belonging to the position measuring system as well as other associated components are not arranged in the same housing. As a result, the position measuring system can be arranged outside the positioner as a remote displacement sensor.

Potentiometers with a slider tap can be resistant to vibrations to a limited extent. In addition, the slider and the resistance track can wear away as a result of electrical erosion after a finite number of movements until they are defective.

In the case of a frequently occurring error pattern, the resistance track can be damaged by abrasion and/or electrical erosion as a result of a slider which cyclically oscillates around a constantly recurring point since the position controller corrects only small control errors. This damage occurs for example, in feedback systems, such as electropneumatic position controllers or electrical variable-speed drives, when they operate with a constant or virtually constant desired value for a long period of time. A defect can be fostered by poor controllability of the control path. Because the control path tends toward oscillation, the period of time for which control is effected at a constant or virtually constant desired value since the associated sensor/potentiometer range is then used for a long time, and the occurrence of a defect increases as the frequency increases.

As a result of the defect, a range of a few angular degrees can often be affected. In this case, the slider can work its way ever further into the material of the resistance track until it finally can no longer make contact. At this point, the potentiometer can be worn and therefore cannot continue to be used for measurement. Thus, more than one point of the sensor may be defective inside an operating range.

In addition, chemical influences can have a negative effect on the service line of slider potentiometers. A defect of the potentiometer can result in the failure of the displacement/position measurement.

The failure of the displacement/position measuring system can result in the failure of the device function. As a result, the position controller carries out a positioning reaction which can be predetermined for the controller and in which the controller remains until the cause of the failure has been rectified. Positioning reactions which can be carried out without a displacement/position measuring system are preset for this purpose. Depending on the respective application, provision can be made to ventilate or vent the drive (i.e., “fail safe”), or to block the drive in the current position (i.e., “fail freeze”).

Since a failure may not be predicted and may not be diagnosed at regular service intervals, such failure can result in unplanned stoppage of the process which can lend to high costs for the user.

In an attempt to increase an availability of the sensor, contactless measuring methods, as disclosed in DE 42 39 635 A1 and DE 10 2007 019 045 A1 for example, have been investigated. These methods have a higher degree of technical complexity than a potentiometer-based measurement scheme, and also have such a high energy consumption that they are rendered unusable for applications in devices which are supplied from a current loop whose power is limited.

### SUMMARY

A method is disclosed for increasing availability of position measuring systems including a potentiometer having a slider tap in a closed control loop and a controller that is formed by a microcontroller which is supplied with a position of the slider via an analog-to-digital converter, the method comprising: shifting an operating range within a sensor range of the potentiometer in a direction of one of two limits of the operating range at least by a distance between the other of the two limits of the operating range and a defective slider position, the shifting including temporarily interrupting an operative connection between a displacement pick-off on an actuator and a potentiometer shaft.

### BRIEF DESCRIPTION OF THE DRAWINGS

The exemplary embodiments of the disclosure will be described in more detail below with reference to the accompanying drawings in which:

FIG. 1 schematically illustrates a known control loop;

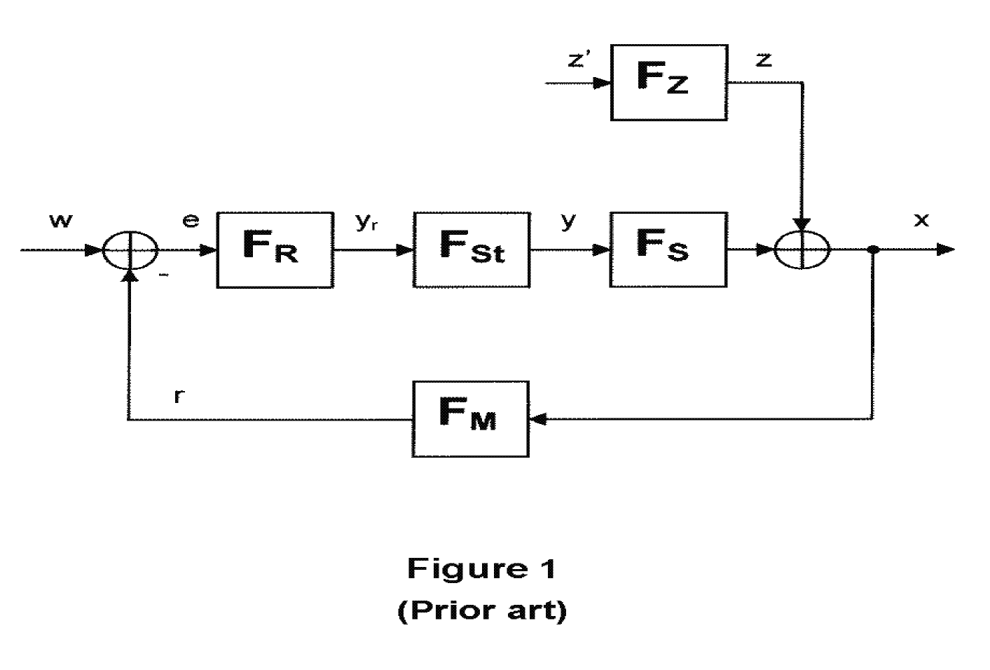

FIG. 2 schematically illustrates an actuator having a potentiometer-based device for determining position in accordance with an exemplary embodiment; and

FIG. 3 illustrates an operating range of a position sensor in a sensor range in accordance with an exemplary embodiment.

### DETAILED DESCRIPTION

Exemplary embodiments are directed to increasing an availability of a potentiometer-based displacement/position measuring system while retaining a measurement principle.

According to exemplary embodiments, a displacement/position measuring system includes potentiometers with a slider tap in a closed control loop, the controller of which is formed by a microcontroller which is supplied with the position of the slider via an analog/digital converter.

Exemplary embodiments involve a technical property of a potentiometer in which a “buried” slider that does not interrupt a resistance track, but rather only a slider tap, is no longer possible at this singular, eroded position.

Exemplary embodiments involve an actual operating range of the potentiometer which is much smaller than its sensor range. The operating range can be shifted within the sensor range in a direction of a second limit of the operating range at least by the distance between the first limit of the operating range and the defective slider position by temporarily interrupting the operative connection between the displacement pick-off on the actuator and the potentiometer shaft outside process tasks.

As a result of the shifting operation, the defective slider position can be outside the operating range, and thus be avoided during the displacement/position measurement.

The shifting direction results from the position of the current operating range within the sensor range.

The operating range can be shifted within the sensor range in a direction of the remote limit of the operating range at least by the distance between the nearest limit of the operating range and the defective slider position.

In order to determine the defective slider position, at least part of the sensor range of the potentiometer can be scanned on request by presetting a sequence of manipulated variables, and an available control loop variable, which represents the position value, can be recorded at a high sampling rate. The exact position of a defective slider position of the potentiometer can be determined by evaluating the control loop variable by way of the associated manipulated variable.

In the case of a displacement/position measuring system with an analog/digital converter, a defective slider position can be detected as an invalid numerical value of the digital output in the operating range of the potentiometer. When starting up the device, the entire operating range within the measurement range of the potentiometer can be scanned at least once. The limits of the operating range in the respective application can then be determined. At a defective slider position, the partial voltage tapped off across the slider is outside the limits of the operating range determined during start-up.

According to another feature of exemplary disclosed embodiments, in order to determine a location of a defective slider position, at least one subrange of the sensor range can be continuously run at a speed which is substantially constant, slow and/or uniform (e.g., as constant, slow, and uniform as possible for a given configuration) and, if a respective defective sensor position is detected, a valid value respectively closest to the position before and after the defective position can be stored.

According to another feature of exemplary disclosed embodiments, a defective slider position which has already been determined can be deliberately approached and its environment is scanned with a small step size. As a result, the location and dimension of the defective slider position are determined precisely and that range of the displacement/position measuring system which needs to be avoided can be kept as small as possible.

According to another feature of exemplary disclosed embodiments, a defective slider position can be detected by means (e.g., computer or processor for monitoring) of unexpected deviations, such as severe discontinuities, sudden changes or severe changes, between a plurality of measured values in comparison with an expected characteristic curve profile of the partial voltage across the slider of the potentiometer. The transfer characteristic of a potentiometer is, for example, linear. Deviations from the expected linearity can be detected in a simple manner.

According to another feature of exemplary disclosed embodiments, the deviation from the expected profile can be specifically detected by comparing the actual profile with a reference which is stored in a nonvolatile manner.

According to an alternative feature of exemplary disclosed embodiments, the location of a defective slider position can be determined by assigning the current reference variable to the feedback variable.

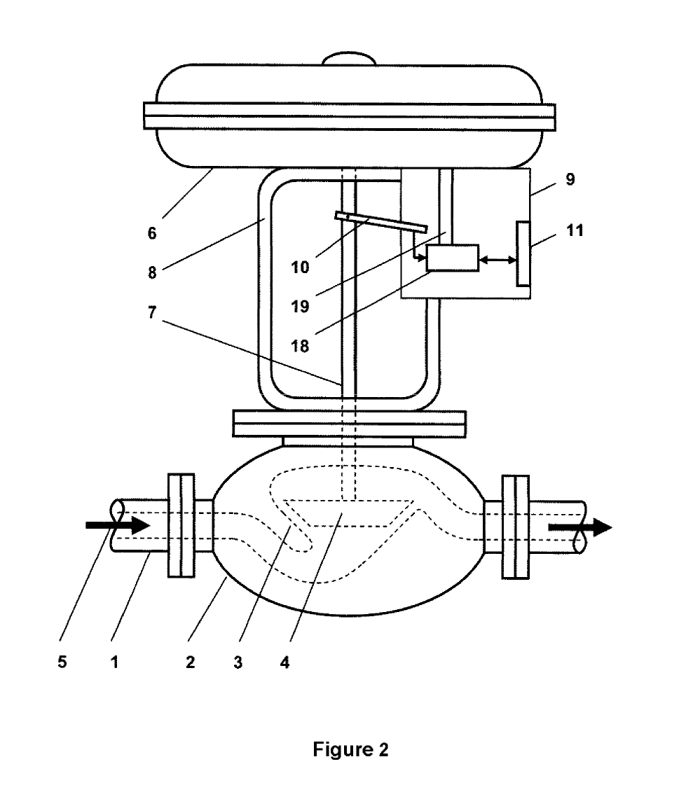

FIG. 2 schematically illustrates an actuator having a potentiometer-based device for determining position in accordance with an exemplary embodiment.

In FIG. 2, a process valve 2 can be installed, as an actuating element, in a pipeline 1. In its interior, the process valve 2 has a closing body 4 which interacts with a valve seat 3 and is intended to control the amount of process medium 5 passing through. The closing body 4 can be linearly operated, via a lifting rod 7, by a pneumatic actuator 6. The actuator 6 is connected to the process valve 2 via a yoke 8. A digital position controller 9 is fitted to the yoke 8. The travel of the lifting rod 7 is reported to the position controller 9 via a position sensor 10.

The detected travel can be compared with a desired value, which is supplied via a communication interface 11 in control electronics 18. The actuator 6 is driven based on the determined control error. The control electronics 18 of the position controller 9 can operate an I/P converter that converts an electrical control error into an adequate control pressure. The I/P converter of the position controller 9 can be connected to the actuator 6 via a pressure medium supply 19.

The position sensor 10 can be connected to the axis of rotation of a potentiometer in the position controller 9 and can include an eye in which a catch on the lifting rod 7 engages.

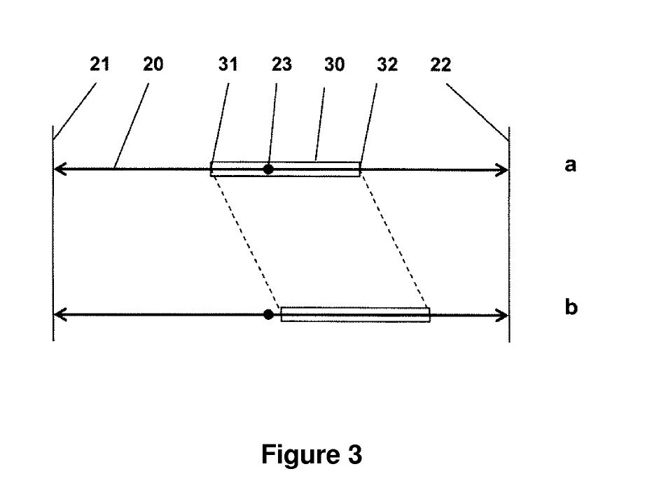

FIG. 3 illustrates an operating range of a position sensor in a sensor range in accordance with an exemplary embodiment. A sensor range 20 of the potentiometer is characterized by its limits 21 and 22 which constitute ends of the sliding track. An actual operating range 30 with its limits 31 and 32, which mark the movement range of the process valve 2, lies within the limits 21 and 22 of the sensor range 20. According to line a of FIG. 3, a defective slider position 23 is within the limits 31 and 32 of the operating range 30 of the position sensor 10.

In an exemplary embodiment, the position sensor 10 can be connected to the axis of rotation of the potentiometer via a slipping clutch. The operative connection between the position sensor 10 on the actuator 6 and the potentiometer shaft of the position controller 9 can be temporarily interrupted by rotating the shafts, which are connected by a slipping clutch, with respect to one another. In this case, the shafts are rotated to such an extent that as shown in line b of FIG. 3, the defective slide position does not fall in the operating range 30 of the sensor range 20. This event occurs because of the operating range 30 being shifted in the direction of the second limit 32 of the operating range 30 at least by a distance between the first limit 31 of the operating range 30 and the defective slider position 23.

The direction of rotation is determined from the position of the limits 31 and 32 of the operating range 30, a position of the limits 21 and 22 of the sensor range 20, and a position of the defective slider position 23. The output relating to the extent of rotation can be measured as, for example, a distance in % or in angular degrees in one direction. If the slipping clutch enables adjustment in equidistant units, the output can also be measured according to the number of adjustment steps.

In an exemplary refinement, the position controller 9 can include an actuator for adjusting the slipping clutch.

In another exemplary embodiment, the position sensor 10 can be connected to the axis of rotation of the potentiometer via a gear mechanism. In this configuration, the operating range 30 can be shifted within the sensor range 20 by rotating the gear wheels with respect to one another in quantized steps while temporarily disengaging the gear wheels involved.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE SYMBOLS

1 Pipeline
2 Process valve
3 Valve seat
4 Closing body
5 Process medium
6 Actuator
7 Valve rod
8 Yoke
9 Position controller
10 Position sensor
11 Communication interface
18 Control electronics
19 Pressure medium supply
20 Sensor range
21, 22 Limit of the sensor range
23 Defective slider position
30 Operating range
31, 32 Limit of the operating range

What is claimed is:

1. A method for increasing availability of position measuring systems including a potentiometer having a slider tap in a closed control loop and a controller that is formed by a microcontroller which is supplied with a position of the slider via an analog-to-digital converter, the method comprising:
shifting an operating range within a sensor range of the potentiometer in a direction of one of two limits of the operating range at least by a distance between the other of the two limits of the operating range and a defective slider position, the shifting including temporarily interrupting an operative connection between a displacement pick-off on an actuator and a potentiometer shaft.

2. The method of claim 1, comprising:
determining a location of a defective slider position by continuously running at least one subrange of the sensor range at a speed which is substantially constant, slow, and uniform; and
storing, when a respective defective sensor position is detected, a value closest to a position before and after the defective position.

3. The method of claim 1, comprising:
approaching a defective slider position which has already been determined; and scanning an environment of the determined defective slider position with a small step size.

4. The method of claim 1, comprising:
detecting a defective slider position as an invalid numerical value of a digital output in the operating range of the potentiometer.

5. The method of claim 1, comprising:
detecting a defective slider position using unexpected deviations between plural measured values in comparison with an expected characteristic curve profile of a partial voltage across the slider of the potentiometer.

6. The method of claim 1, comprising:
detecting a deviation from an expected profile by comparing an actual profile with a reference that is stored in a nonvolatile manner.

7. The method of claim 1, comprising:
determining a location of a defective slider position by assigning a current reference variable to a feedback variable.
